(19) United States
(12) Patent Application Publication
(10) Pub. No.: US 2018/0098460 A1
(43) Pub. Date: Apr. 5, 2018

(54) LIQUID COOLING HEAT DISSIPATION MODULE

(71) Applicant: MSI Computer (Shenzhen) Co., Ltd, Guangdong Province (CN)

(72) Inventors: Li-Li Ko, New Taipei City (TW); Yi-Di Huang, New Taipei City (TW); Hung Chang, New Taipei City (TW); Min-Lang Chen, New Taipei City (TW); Hsueh-Lung Cheng, New Taipei City (TW)

(73) Assignee: MSI Computer (Shenzhen) Co., Ltd, Guangdong Province (CN)

(21) Appl. No.: 15/361,080

(22) Filed: Nov. 25, 2016

(30) Foreign Application Priority Data
Sep. 30, 2016 (TW) 105214883

(51) Int. Cl. H05K 7/20

(52) U.S. Cl. CPC H05K 7/20263

(57) ABSTRACT

A liquid cooling heat dissipation module adapted to be disposed on a heat source of a motherboard is provided. The liquid cooling heat dissipation module includes a heat conducting member, a first tank, a pump and a first agitating member. The heat conducting member is adapted to be thermally coupled to the heat source. The first tank is filled with cooling liquid, and the cooling liquid thermally couples with the heat conducting member. The pump is connected through with the first tank to drive the cooling liquid to flow along a direction. The first agitating member is disposed on a flowing path of the cooling liquid so as to homogenize a temperature of the cooling liquid.

### CROSS-REFERENCE TO RELATED APPLICATION

This application claims the priority benefit of Taiwan application serial no. 105214883, filed on Sep. 30, 2016. The entirety of the above-mentioned patent application is hereby incorporated by reference herein and made a part of this specification.

### BACKGROUND OF THE INVENTION

### Field of the Invention

The present invention generally relates to a heat dissipation module, and more particularly, to a liquid cooling heat dissipation module.

### Description of Related Art

In general, a central processing unit (CPU) of a motherboard is usually configured with a plurality of heat dissipation fins thereon so that heat generated by the CPU can be transmitted to the heat dissipation fins, and then the CPU can be maintained at a normal operating temperature range through using a fan to lower a temperature of the heat dissipation fins and thereby prevent a damage due to overheat. However, as technology advances, with the continual enhancement in CPU clock, more heat is generated during the operating of CPU, and traditional heat dissipation devices which adopt the heat dissipation fins for dissipating heat are no longer applicable. Therefore, how to provide an approach sufficient to dissipate heat from a processing chip is indeed an imperative issue to be solved by relevant personnel.

### SUMMARY OF THE INVENTION

The invention provides a liquid cooling heat dissipation module capable of providing more favorable heat dissipation effect.

A liquid cooling heat dissipation module of the invention is adapted to be disposed on a heat source of a motherboard, and the liquid cooling heat dissipation module includes a heat conducting member, a first tank, a pump and a first agitating member. The heat conducting member is adapted to be thermally coupled to the heat source. The first tank is filled with cooling liquid, wherein the cooling liquid thermally couples with the heat conducting member. The pump is connected through with the first tank to drive the cooling liquid to flow along a direction. The first agitating member is disposed on a flowing path of the cooling liquid so as to homogenize a temperature of the cooling liquid.

In one embodiment of the invention, the first agitating member includes a plurality of blades or a rotor.

In one embodiment of the invention, the liquid cooling heat dissipation module further includes a second tank connected through with the first tank, and the first agitating member is disposed in the second tank.

In one embodiment of the invention, the liquid cooling heat dissipation module further includes a third tank and a second agitating member. The third tank is connected through with the first tank. The second agitating member is disposed in the third tank.

In one embodiment of the invention, the second agitating member includes a plurality of blades or a rotor.

In one embodiment of the invention, the second tank and the third tank is symmetrically disposed at two sides of the first tank, and the first tank, the second tank and the third tank are connected through with each other by means of serial connection.

In one embodiment of the invention, the liquid cooling heat dissipation module further includes a leak detector for detecting whether the cooling liquid is leaked.

In one embodiment of the invention, the leak detector includes a liquid level detector disposed at the first tank for detecting a level of the cooling liquid in the first tank.

In one embodiment of the invention, the leak detector includes a temperature detector disposed in the first tank for detecting the temperature of the cooling liquid in the first tank.

In one embodiment of the invention, the leak detector includes a humidity detector disposed outside and underneath the first tank for detecting whether the cooling liquid flows out of the first tank.

In view of the above, the liquid cooling heat dissipation module of the invention cools the heat source by means of liquid cooling, such that heat generated during the operation of the heat source is transmitted to the cooling liquid within the first tank through the heat conducting member, the cooling liquid after absorbing the heat can undergo a phase change to take away even more heat, and the cooling liquid in response to an actuation of the first agitating member enables the temperature of the cooling liquid to be more uniform or homogenized. In addition, the liquid cooling heat dissipation module of the invention can be a multi-tank so as to provide a larger space for accommodating more cooling liquid. Moreover, the liquid cooling heat dissipation module of the invention may further include the leak detector for detecting whether the cooling liquid is leaked, and thereby prevents the motherboard from being damaged due to a leakage of the cooling liquid.

Several exemplary embodiments accompanied with figures are described in detail below to further describe the disclosure in details.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a liquid cooling heat dissipation module according to an embodiment of the invention.

FIG. 2 is a schematic diagram of FIG. 1 illustrated from another view angle.

FIG. 3 is a schematic diagram illustrating a flowing path of the cooling liquid in the liquid cooling heat dissipation module of FIG. 1.

FIG. 4 and FIG. 5 are schematic diagrams respectively illustrating a plurality of liquid cooling heat dissipation modules according to other embodiments of the invention.

### DESCRIPTION OF THE EMBODIMENTS

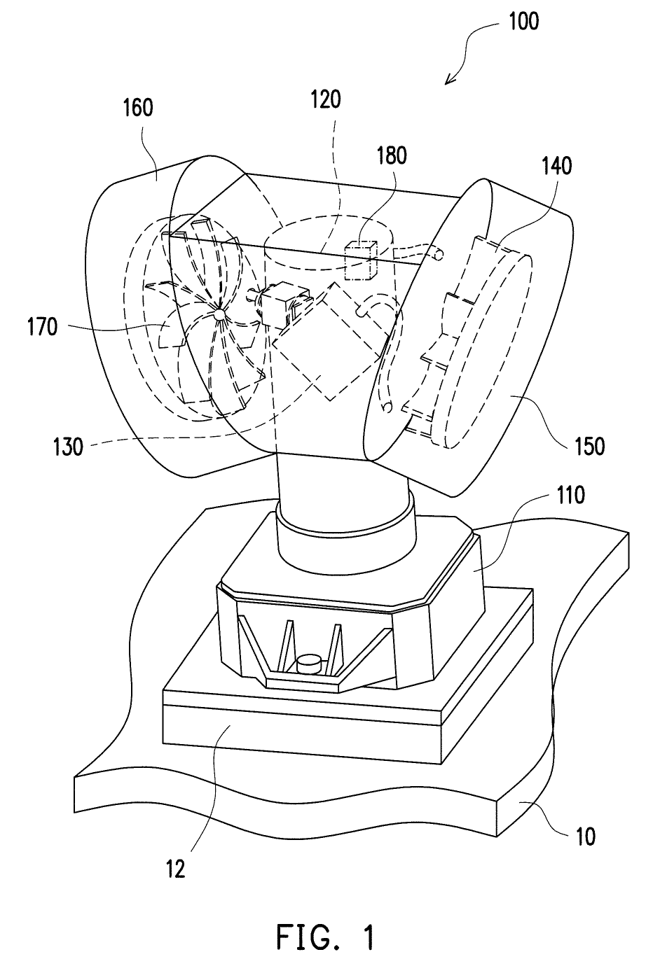

FIG. 1 is a schematic diagram illustrating a liquid cooling heat dissipation module according to an embodiment of the invention. Referring to FIG. 1, the liquid cooling heat dissipation module 100 of the invention is adapted to be disposed on a heat source 12 of a motherboard 10. The heat source 12 is, for example, a central processing unit (CPU), but the type of the heat source 12 is not limited thereto. The liquid cooling heat dissipation module 100 includes a heat conducting member 110, a first tank 120, a pump 130, a first agitating member 140, a second tank 150, a third tank 160, and a second agitating member 170.

The heat conducting member 110 is adapted to be thermally coupled to the heat source 12 and the first tank 120, and the first tank 120 is filled with cooling liquid to enable heat generated by the heat source 12 to be transmitted to the cooling liquid within the first tank 120 through the heat conducting member 110. In the present embodiment, the cooling liquid is, for example, water; however, in other embodiments, the cooling liquid may also be other liquids with high specific heat which can lower a temperature of the heat source 12 by generating a phase change after absorbing the heat. The cooling liquid may further speed up a cooling rate of the cooling liquid by having pipelines (not shown) to pass through a plurality of heat dissipation fins (not shown) nearby a fan (not shown).

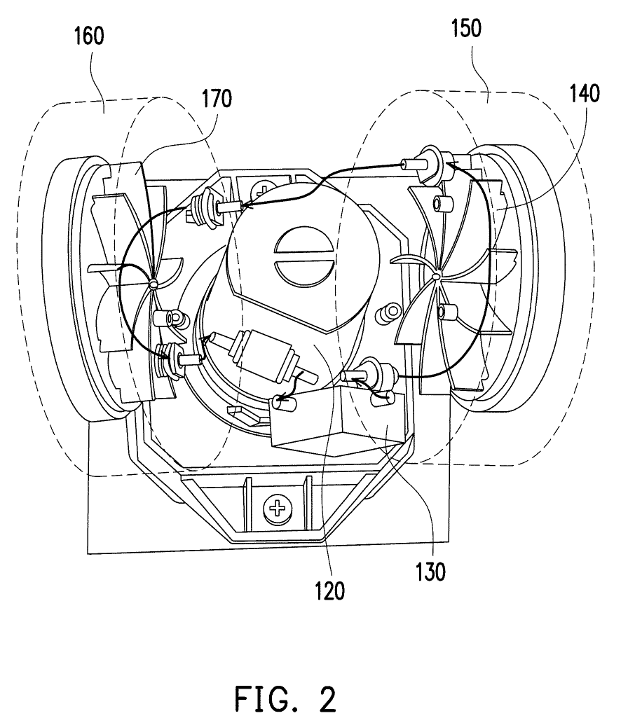

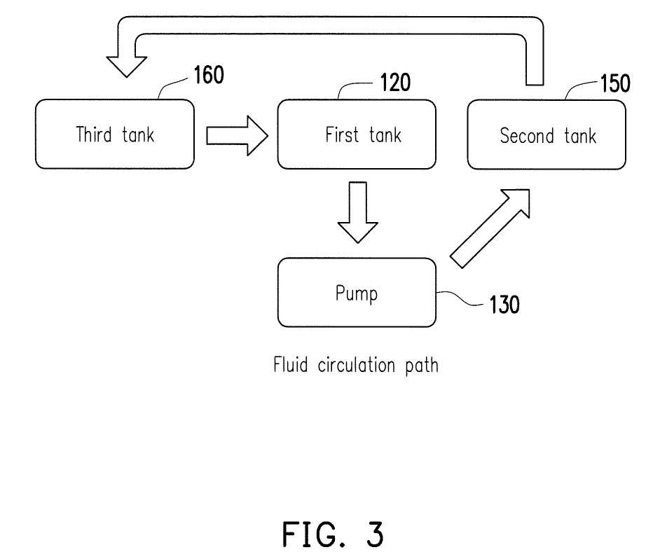

FIG. 2 is a schematic diagram of FIG. 1 illustrated from another view angle. FIG. 3 is a schematic diagram illustrating a flowing path of the cooling liquid in the liquid cooling heat dissipation module of FIG. 1. It is to be explained that, in order to show a flowing path of the cooling liquid more clearly, FIG. 2 hides an outer casing of the liquid cooling heat dissipation module 100 which is outside the first tank 120. In addition, in order to show the flowing path of the cooling liquid more clearly, various element in FIG. 3 are merely illustrated with schematic blocks.

Referring to FIG. 1 and FIG. 3 at the same time, the pump 130 is connected through with the first tank 120 and the second tank 150 so as to drive the cooling liquid to flow along a direction. In the present embodiment, the second tank 150 and the third tank 160 are symmetrically disposed at two sides of the first tank 120. With such configuration, in addition to being more aesthetic, it can also prevent the elements on the motherboard 10 from structurally interfering with each other. Certainly, in other embodiments, the second tank 150 and the third tank 160 may also be not symmetrically disposed at the two sides of the first tank 120 as long as the elements on the motherboard 10 can be prevented from structurally interfering with each other.

In the present embodiment, the first tank 120, the pump 130, the second tank 150, and the third tank 160 are connected through with each other by means of serial connection. As shown in FIG. 2 and FIG. 3, in the present embodiment, the flowing path of the cooling liquid is, for example, a circulation passing through the first tank 120, the pump 130, the second tank 150, the third tank 160, and then back to the first tank 120, sequentially. Certainly, FIG. 2 and FIG. 3 merely illustrate one of the flowing paths, and a designer should be able to select an appropriate flowing direction and an appropriate path for the cooling liquid.

The liquid cooling heat dissipation module 100 of the present embodiment has three tanks, and thus can accommodated a large volume of the cooling liquid for quickly lowering the temperature of the heat source 12. Certainly, in other embodiments, location and configuration relationships between the first tank 120, the second tank 150 and the third tank 160 are not limited thereto, and the number of the tanks may also be less or more and is not limited to three. In other embodiment, the three tanks may also be replaced by a larger volume tank, or the number of the tanks may also be two or more than four.

In addition, in order for the temperature of the cooling liquid to be more uniform, the first agitating member 140 and the second agitating member 170 are respectively disposed on the flowing path of the cooling liquid so as to homogenize the temperature of the cooling liquid. More specifically, in the present embodiment, the first agitating member 140 and the second agitating member 170 are respectively disposed in the second tank 150 and the third tank 160, and the first agitating member 140 and the second agitating member 170 respectively include a plurality of blades. When the cooling liquid is driven by the pump 130 to circulated within the first tank 120, the second tank 150 and the third tank 160, the flow of the cooling liquid within the second tank 150 and the third tank 160 drives the first agitating member 140 and the second agitating member 170 into rotation so that the temperature of the cooling liquid with in the second tank 150 and the third tank 160 becomes more uniform, thereby enhancing the heat dissipation efficiency.

In the present embodiment, actuations of the first agitating member 140 and the second agitating member 170 do not require supplying additional power such that the first agitating member 140 and the second agitating member 170 are driven by merely the flow of the cooling liquid; however, in other embodiments, the first agitating member 140 and the second agitating member 170 may also be actuated by supplying power or applying additional magnetic field such that the first agitating member 140 and the second agitating member 170 may also be driven into rotation by an additionally applied magnetic field.

It is to be noted that, in order to prevent a situation in which the motherboard 10 is damaged due to a leakage of the cooling liquid caused by a tank rupture, in the present embodiment, the liquid cooling heat dissipation module 100 further includes a leak detector 180 configured to detect whether the cooling liquid is leaked. More specifically, the leak detector 180 of the present embodiment includes a liquid level detector disposed in the first tank 120 for detecting whether a level of the cooling liquid in the first tank 120 is within a correct range. If the leak detector 180 detects that the level of the cooling liquid in the first tank 120 is insufficient, then it indicates that a leakage may occur, and at this moment, the leak detector 180 can send a message, which notifies that the level of the cooling liquid in the first tank 120 is insufficient, to a warning device (not shown), so as to inform a user.

The warning device may be a device, such as a buzzer or a LED light, which informs the user through auditory, visual or other means; and certainly, the type of the warning device is not limited thereto. Otherwise, the leak detector 180 can be signally connected to a CPU or a controller, and the CPU or the controller after receiving the message, which notifies that the level of the cooling liquid in the first tank 120 is insufficient, can forcibly shut down the apparatus to prevent the motherboard 10 from being damaged. Besides, in other embodiments, the leak detector 180 may also be disposed at the other tank, such that the location of the leak detector 180 is not limited thereto.

Moreover, the type of the leak detector 180 is not limited to the one described in the above, and implementations of other types of the leak detector 180 will be described in the following. It is to be explained that, in the following embodiments, elements/components that are the same or similar those of the previous embodiment will be represented by the same or similar notations/reference numerals, and thus will not be elaborated or repeated.

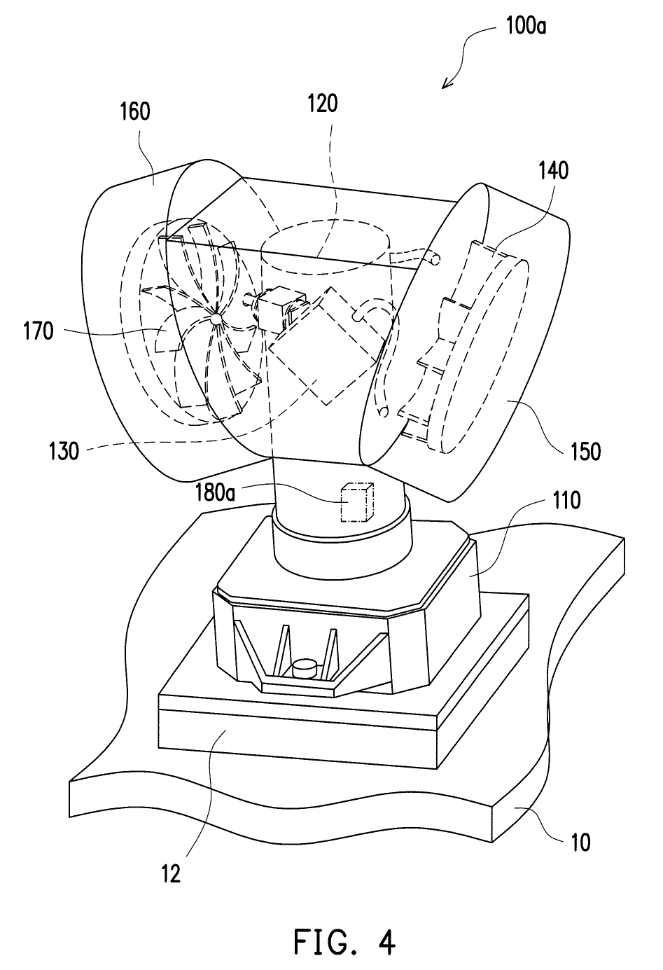

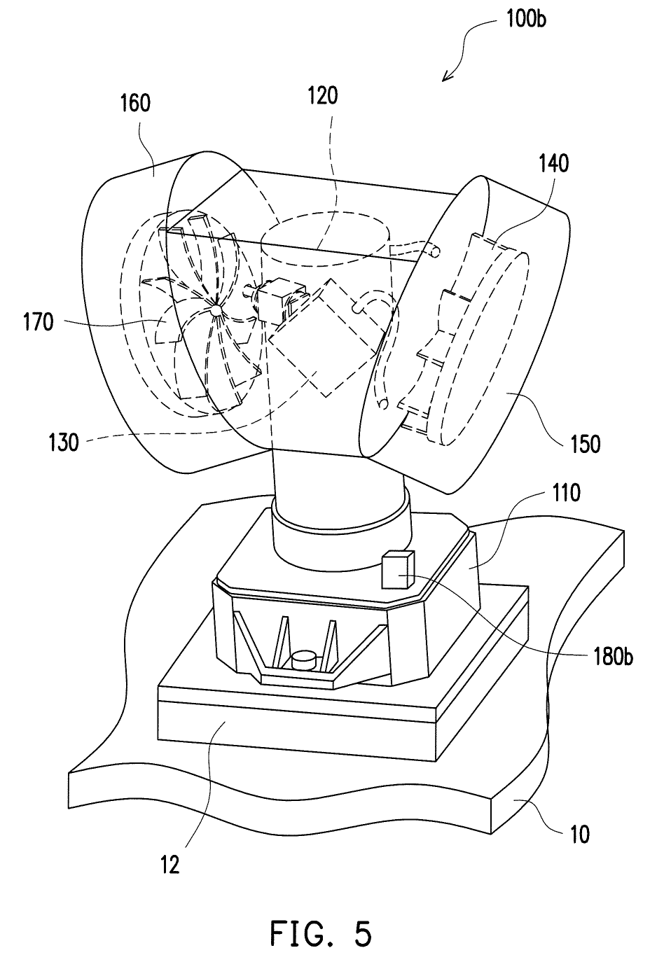

FIG. 4 and FIG. 5 are schematic diagrams respectively illustrating a plurality of liquid cooling heat dissipation modules according to other embodiments of the invention. Referring to FIG. 4, a main difference between the liquid cooling heat dissipation module 100a of FIG. 4 and the liquid cooling heat dissipation module 100 of

FIG. 1 lies in that, in the present embodiment, the leak detector 180a includes a temperature detector disposed in the first tank 120 for detecting the temperature of the cooling liquid in the first tank 120. If the leak detector 180a detects that the temperature of the cooling liquid in the first tank 120 exceeds a preset value or a set value, then it indicates that the amount of the cooling liquid may be insufficient for lowering the temperature. At this moment, the leak detector 180a can send a message, which notifies that the amount of the cooling liquid in the first tank 120 is insufficient, to the warning device, the CPU or the controller, so as to inform the user. Similarly, in other embodiments, the leak detector 180a may also be disposed in the other tank, such that the location of the leak detector 180a is not limited thereto.

Referring to FIG. 5, a main difference between the liquid cooling heat dissipation module 100b of FIG. 5 and the liquid cooling heat dissipation module 100 of FIG. 1 lies in that, in the present embodiment, the leak detector 180b includes a humidity detector disposed outside and underneath the first tank 120 for detecting whether the cooling liquid flows out of the first tank 120. In general, due to the heat generated during the operation of the motherboard 10, a region above the motherboard 10 is relatively dry (low in humidity); and thus, if the leak detector 180b detects that the humidity is higher than a preset value or a set value, then it may signify a leakage of the cooling liquid. At this moment, the leak detector 180 can send a message, which indicates a detection of a high humidity, to the warning device, the CPU or the controller, so as to inform the user. Similarly, in other embodiment, the leak detector 180a may also be disposed underneath the other tank, such that the location of the leak detector 180a is not limited thereto.

In summary, the liquid cooling heat dissipation module of the invention cools the heat source by means of liquid cooling, such that the heat generated during the operation of the heat source is transmitted to the cooling liquid within the first tank through the heat conducting member, the cooling liquid after absorbing the heat can undergo a phase change to take away even more heat, and the cooling liquid in response to the actuation of the first agitating member enables the temperature of the cooling liquid to be more uniform or homogenized. In addition, the liquid cooling heat dissipation module of the invention can be a multi-tank so as to provide a larger space for accommodating more cooling liquid. Moreover, the liquid cooling heat dissipation module of the invention may further include the leak detector for detecting whether the cooling liquid is leaked, and thereby prevents the motherboard from being damaged due to a leakage of the cooling liquid.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A liquid cooling heat dissipation module, adapted to be disposed on a heat source of a motherboard, the liquid cooling heat dissipation module comprising:
a heat conducting member, adapted to be thermally coupled to the heat source;
a first tank, filled with cooling liquid, wherein the cooling liquid thermally couples with the heat conducting member;
a pump, connected through with the first tank to drive the cooling liquid to flow along a direction; and
a first agitating member, disposed on a flowing path of the cooling liquid to homogenize a temperature of the cooling liquid.

2. The liquid cooling heat dissipation module as recited in claim 1, wherein the first agitating member comprises a plurality of blades or a rotor.

3. The liquid cooling heat dissipation module as recited in claim 1, further comprising:
a second tank, connected through with the first tank, the first agitating member disposed in the second tank.

4. The liquid cooling heat dissipation module as recited in claim 3, further comprising:
a third tank, connected through with the first tank; and
a second agitating member, disposed in the third tank.

5. The liquid cooling heat dissipation module as recited in claim 4, wherein the second agitating member comprises a plurality of blades or a rotor.

6. The liquid cooling heat dissipation module as recited in claim 4, wherein the second tank and the third tank are symmetrically disposed at two sides of the first tank, and the first tank, the second tank and the third tank are connected through with each other by means of serial connection.

7. The liquid cooling heat dissipation module as recited in claim 1, further comprising:
a leak detector, configured to detect whether the cooling liquid is leaked.

8. The liquid cooling heat dissipation module as recited in claim 7, wherein the leak detector comprises a liquid level detector disposed at the first tank for detecting a level of the cooling liquid in the first tank.

9. The liquid cooling heat dissipation module as recited in claim 7, wherein the leak detector comprises a temperature detector disposed with in the first tank for detecting the temperature of the cooling liquid in the first tank.

10. The liquid cooling heat dissipation module as recited in claim 7, wherein the leak detector comprises a humidity detector disposed outside and underneath the first tank for detecting whether the cooling liquid flows out of the first tank.
